(19) United States
(12) Patent Application Publication
(10) Pub. No.: US 2023/0054638 A1
(43) Pub. Date: Feb. 23, 2023

(54) ION GUN AND METHODS FOR SURFACE TREATMENT

(71) Applicant: The Regents of the University of California, Oakland, CA (US)

(72) Inventors: Hartmut G. HAEFFNER, Oakland, CA (US); Sara Lambert MOURADIAN, Oakland, CA (US); Megidish Eli MAGIDASH, Oakland, CA (US); Nicole Sarah GREENE, Oakland, CA (US)

(73) Assignee: The Regents of the University of California, Oakland, CA (US)

(21) Appl. No.: 17/758,198

(22) PCT Filed: Jan. 4, 2021
(86) PCT No.: PCT/US2021/012054

§ 371 Date: Jun. 29, 2022

Related U.S. Application Data
(60) Provisional application No. 62/956,491, filed on Jan. 2, 2020.

(51) Int. Cl. H01J 37/147; H01J 37/21; H01J 37/08

(52) U.S. Cl. CPC H01J 37/1471; H01J 37/21; H01J 37/08

(57) ABSTRACT

An ion gun includes a confinement vessel defining a chamber therein; a plasma source configured to provide ions in the chamber; and at least one acceleration and focusing electrode disposed within the chamber and positioned to receive ions from the plasma source, and to accelerate and focus the ions received to be delivered to an underlying surface. The at least one acceleration and focusing electrode is structured to provide an aperture therethrough to provide optical access to a high numerical aperture optical device.

### CROSS-REFERENCE TO RELATED APPLICATIONS

This application claims priority benefit from U.S. provisional patent application No. 62/956,491, filed on Jan. 2, 2020, the entire content of which is incorporated herein by reference.

### STATEMENT OF GOVERNMENT INTEREST

The present invention was made with government support under Grant Number 1818914 awarded by the National Science Foundation (NSF). The U.S. government has certain rights in the invention.

### BACKGROUND

### 1. Technical Field

Currently claimed embodiments of the invention are directed to ion sources, and more particularly to ion guns, ion traps and methods for surface treatment therewith.

### 2. Discussion of Related Art

Ion guns are known to be employed to provide surface treatments for systems such as ion traps, and other devices, and to reduce electromagnetic noise of such systems. For example, electromagnetic noise from surfaces is one of the limiting factors for the performance of solid state and trapped ion quantum information processing architectures. This introduces gate errors and reduces the coherence time of the systems. In many solid state systems the surface noise decoheres the qubit and reduces entanglement rate and fidelity. For trapped ions and Rydberg atoms, the electrical noise impacts the gate fidelities as the electromagnetic force mediates the coupling between the qubits in these systems. Most scalable ion trap architectures rely on small ion-electrode distances to reconfigure the ion strings. Especially, as the ions gets closer to the electrode, the electric field noise from the surface excites the ion motion, generating decoherence of the motion state of the ion crystal. Since almost all multi-ion quantum gates use the motion state of the ion crystal as a quantum bus to transfer quantum information from one ion to the other, the surface noise tends to limit the obtainable gate fidelities in these scalable ion trap quantum computing architectures. Therefore, there is a great interest in reducing the electromagnetic noise generated at the surface of solid systems.

Surface treatment using ion bombardment from ion guns has shown to reduce electromagnetic surface noise by two orders of magnitude. In this procedure, ions usually from noble gasses, are accelerated towards the surface with energies of 300 eV to 2 keV. The physical mechanism for the surface noise is still under research. It has been shown experimentally, however, that such surface treatment reduces the noise by two orders of magnitude. It has also been shown experimentally that surface noise may increase after some time. Thus, periodic in-situ surface treatment may be required to maintain low motional decoherence. Up until now commercial ion guns have been used in these experiments.

While these ion guns can supply the ion flux and energy needed to prepare the surface with the desired quality, they are bulky and limit laser access making them incompatible with the requirements for ion trap quantum computing.

While milling of ion traps could be done ex-situ, this requires exposure to atmosphere or transport of the ion trap in a sealed package and placing it as such in the vacuum chamber. In the former case recontamination takes place, the latter case is rather complicated and makes periodic cleaning very difficult. Another alternative procedure could be to mount the trap on a movable bellow to transport it under vacuum from an ion gun to an area with sufficient optical access. This method, however, requires a substantially larger vacuum apparatus and causes problems with the electrical connections.

To address the above issues, some embodiments as disclosed herein enable in-situ surface treatment with an ion gun of a disclosed design without sacrificing high optical access through the ion gun.

### SUMMARY

An embodiment of the present invention is directed to an ion gun that includes a confinement vessel defining a chamber therein; a plasma source configured to provide ions in the chamber; and at least one acceleration and focusing electrode disposed within the chamber and positioned to receive ions from the plasma source, and to accelerate and focus the ions received to be delivered to an underlying surface. The at least one acceleration and focusing electrode is structured to provide an aperture therethrough to provide optical access to a high numerical aperture optical device.

An ion trap according to another embodiments of the current invention includes an ion gun incorporated therein according to an embodiment of the current invention.

An ion gun assembly according to another embodiments of the current invention includes an ion gun and a high numerical aperture optical device. The ion gun includes a confinement vessel defining a chamber therein; a plasma source configured to provide ions in the chamber; and at least one acceleration and focusing electrode disposed within the chamber and positioned to receive ions from the plasma source and accelerate and focus the ions received to be delivered to an underlying surface. The at least one acceleration and focusing electrode is structured to provide an aperture therethrough to provide optical access to the high numerical aperture optical device.

A method of treating a surface of an ion trap during use according to another embodiments of the current invention includes providing an ion gun according to an embodiment of the current invention incorporated into the ion trap, and using the ion gun to treat an inner surface region of the ion trap at a plurality of different times while the ion gun remains incorporated into the ion trap.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise.

FIG. 1 is schematic diagram of an ion gun according to an embodiment of the present invention;

FIG. 2 is a schematic diagram of the ion gun showing the various voltage sources used to bias the various electrodes according to an embodiment of the present invention;

FIG. 3 is a schematic diagram of an ion gun assembly including the ion gun coupled to a high numerical aperture device according to an embodiment of the present invention;

FIGS. 4A-4D are various side views of the ion gun showing dimensions of structural components of the ion gun according to some embodiments of the present invention; and

FIG. 5 is a schematic diagram illustrating a surface treatment technique of gold (Au) with Argon ions (Ar⁺) according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention.

According to some embodiments an ion gun is provided having a structure which allows for high optical access through the ion gun. The ion gun is compatible with high numerical aperture access.

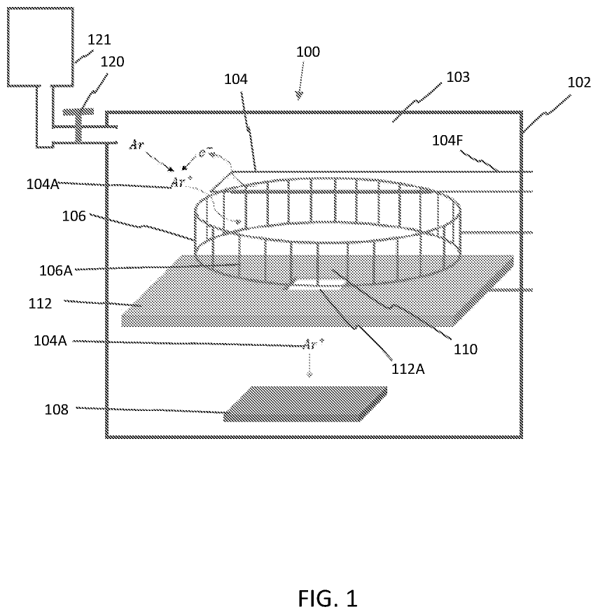

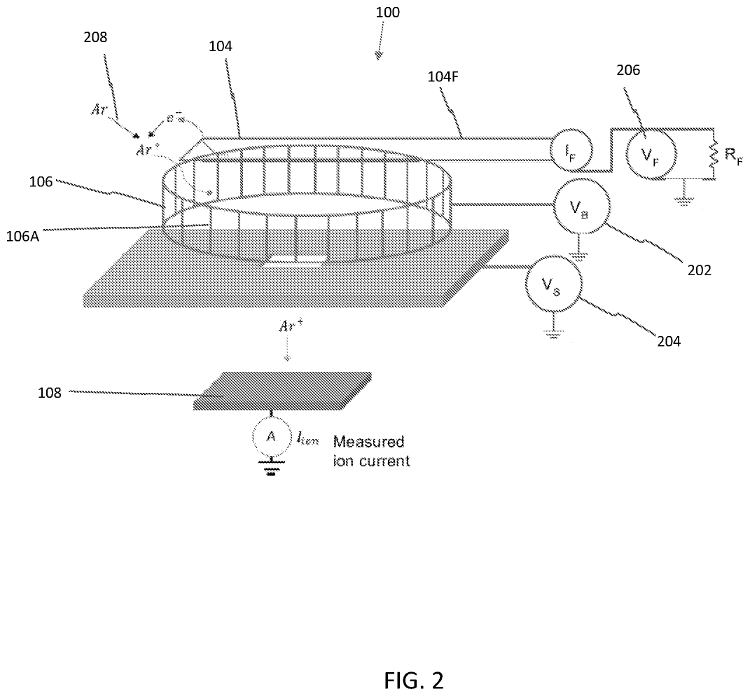

FIG. 1 is schematic diagram of an ion gun 100, according to an embodiment of the present invention. The ion gun 100 includes a confinement vessel 102 defining a chamber 103 therein. The ion gun 100 further includes a plasma source 104 configured to provide ions (e.g., Ar⁺) 104A in the chamber 103. The ion gun 100 further includes at least one acceleration and focusing electrode 106 disposed within the chamber 103 and positioned to receive ions (e.g., Ar⁺) from the plasma source 104, and to accelerate and focus the ions 104A received to be delivered to an underlying surface 108. The ions (e.g., Ar⁺) imping the surface 108. Current Iᵢₒₙ generated by the impact of the impinging ions (e.g., Ar⁺) can also be measured (see, FIG. 2). The at least one acceleration and focusing electrode 106 is structured to provide an aperture 110 therethrough to provide optical access to a high numerical aperture optical device. In an embodiment, the underlying surface 108 that is impinged by the ions (e.g., Ar+) can be a surface of an ion trap.

In an embodiment, the at least one acceleration and focusing electrode 106 includes a basket electrode 106A formed in a cylindrical shape, configured and arranged to accelerate and focus the ions 104A in an axial direction of the basket electrode 106A. In an embodiment, the at least one acceleration and focusing electrode 106 further includes a shield 112 arranged substantially perpendicular to and spaced apart from the basket electrode 106A in an axial direction therefrom. The shield 112 defines an aperture 112A therethrough. In an embodiment, the at least one acceleration and focusing electrode 106 is less than about 1.5 cm in height. The geometry of the shield 112 allows for relatively high numerical aperture access.

FIG. 2 is a schematic diagram of the ion gun 100 showing the various voltages sources used to bias various electrodes, according to an embodiment of the present invention. As shown in FIG. 2, the ion gun 100 further includes a first voltage source 202 connected to the basket electrode 106A to provide a voltage V_{B}. The ion gun also 100 includes a second voltage source 204 connected to the shield 112 to provide a voltage V_{S}. In an embodiment, during operation, the first voltage source 202 provides a voltage V_{B} of at least 100 V to about 2 kV, and the second voltage source 204 provides a voltage V_{S} of at least 0 V to about V_{B}. In an embodiment, during operation, the first voltage source 202 provides a voltage V_{B} of at least 200 V to about 500 V, and the second voltage source 204 provides a voltage V_{S} of at least 0 V to about V_{B}. In an embodiment, during operation, the first voltage source 202 provides a voltage V_{B} of about 300 V, and the second voltage source 204 provides a voltage V_{S} of 300 V or less.

In an embodiment, the plasma source 104 includes a filament 104F connected to a power supply 206 to provide energetic electrons to form a plasma from a supply gas 208 (e.g., Ar). The filament 104F generates electrons which ionize the supply gas (e.g., Ar) introduced into the chamber 103. In an embodiment, the plasma source 104 includes a control valve 120 (shown in FIG. 1) to allow the supply gas 208 to be delivered from a gas reservoir 121 to the chamber 103. In an embodiment, the control valve 120 can be a high precision valve configured to provide gas, such as a high-purity noble gas (e.g., Ar), to supply the gas into the chamber 103, which may be under ultra-high vacuum (UHV). Vacuum pumps (not shown) are provided to achieve the desired vacuum. In some embodiments, the ionized gas may be a noble gas such as Ar. However, some other noble gas, or a gas other than a noble gas can also be used.

In an embodiment, during operation, a voltage V_{F} is applied to the filament 104F by the power supply 206. In embodiment, the power supply 206 supplies a current I_{F} of at least 2.6 A to about 10 A to the filament 104F. In an embodiment, the power supply 206 supplies a current I_{F} of at least 4 A to about 17 A to the filament 104F. In an embodiment, the power supply 206 supplies a current I_{F} of about 5.5 A to the filament 104F.

Table 1 provides various operating voltage and current values to operate the ion gun.

TABLE 1

| | I_{F} | V_{F} | V_{B} | V_{S} |
|---|---|---|---|---|
| Operating Value | 5.5 A | 30 V | 300 V | 300 V |
| Working Range | 4 A-7 A | 5 V-50 V | 200 V-500 V | 0 V-V_{B} |
| Acceptable Range | 2.6 A (threshold)- | 1 V-V_{B} | 100 V-2 kV | 0 V-V_{B} |
| (not tested) | 10 A (breaking) | | | |

According to some embodiments, the ion gun 100 can be based on the shape and arrangement of the plasma source 104, including electron source or filament 104F, and the at least one acceleration and focusing electrode 106. According to some embodiments, the electron source 104 and the at least one acceleration and focusing electrode 106 may be arranged for more efficient ion production and acceleration onto the surface 108, while at the same time accommodating a high numerical optical aperture. This arrangement allows for an efficient in-situ surface treatment without compromising trap operating parameters. In an embodiment, the at least one acceleration and focusing electrode 106 may include transparent electrodes to increase the ion yield and prevent charging while preserving optical access.

According to some embodiments, for cleaning using the ion gun 100, one parameter in a surface treatment procedure is the sputtering rate which measures the material removal rate. The sputtering yield is given by:

$$Sputtering Rate ( nm / min ) = \frac{Sputtering Yield \times Ion Flux}{Density} .$$

The sputtering yield depends on the material properties and the ion energy. The ion flux and energy will be dependent on the pressure in the chamber, electron energy and acceleration voltages. For a stable operation of the ion gun 100 one can measure the ion flux and feedback on either the electron emission current or pressure. Parameters of interest for the ion gun 100 may include ion gun dimensions, distance between the ion gun 100 and surface 108 to be treated, operating voltages and currents, and gas type and pressure.

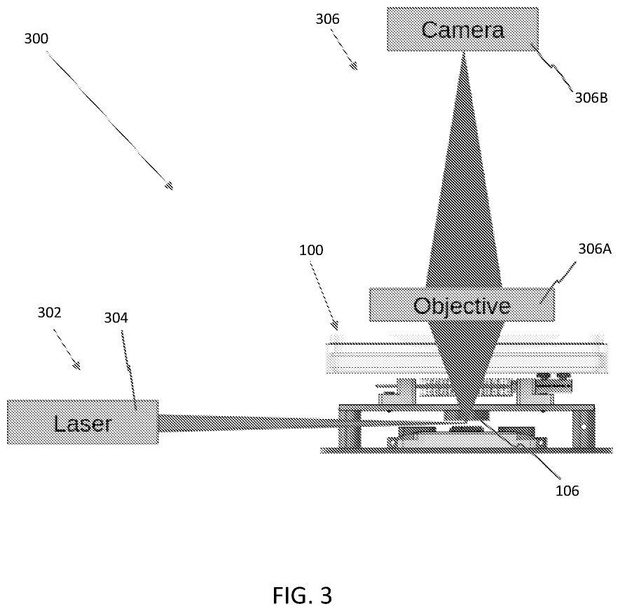

FIG. 3 is a schematic diagram of an ion gun assembly 300 including the ion gun 100 coupled to a high numerical aperture device 302, according to an embodiment of the present invention. The ion gun assembly 300 includes the above described ion gun 100 and a high numerical aperture optical device 302. In an embodiment, the high numerical aperture optical device includes a laser 304. The at least one acceleration and focusing electrode 106 of the ion gun 100 is structured to provide an aperture therethrough to provide optical access to the high numerical aperture optical device 302. In an embodiment, an optical visualization system 306 can also be provided for viewing effects of the ion sputtering on the surface 108. The optical visualization system 306 can include an objective lens 306A and a camera 306B such as a charge coupled device (CCD) camera.

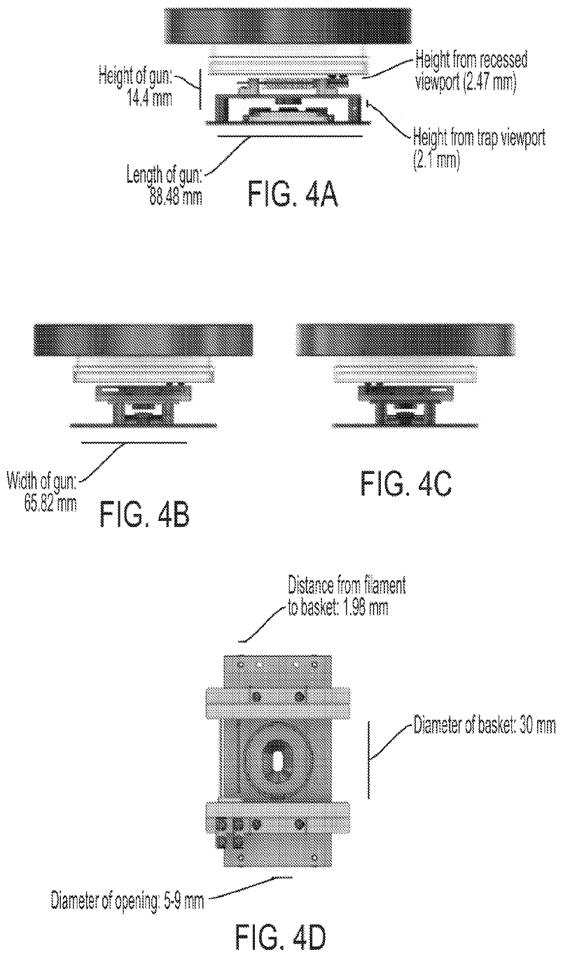

FIGS. 4A-4D are various side views of the ion gun 100 showing dimensions of structural components of the ion gun, according to some embodiments of the present invention. FIG. 4A is a lateral view showing the length of the ion gun of about 88 mm and a height of the gun of about 14 mm. FIG. 4B is a lateral view showing a width of the ion gun of about 65 mm. FIG. 4D is a top view of the ion gun showing an example dimensions of the basket electrode 106A, the position of the basket electrode 106A relative to the filament 104F, and the diameter (e.g., 5-9 mm) of the opening or aperture 112A in the shield 112 (see, FIG. 1). This illustrate that the ion gun 100 is a relatively compact and small device that can fit in a small space. Table 2 below provides example dimensions of compact ion gun according to some embodiments of the resent invention. However, the ion gun and components of the ion gun are not limited to the listed dimensions as other dimensions can also be used depending on a desired application or customer specification.

TABLE 2

| | | | | | | | | Distance |
|---|---|---|---|---|---|---|---|---|
| | | | | Distance | Distance | | Shield | between |
| | | | | from | from | Basket | Opening | Filament |
| | Length | Width | Height | Surface | Viewport | Diameter | Diameter | and Basket |
| Operating | 88.48 mm | 65.82 mm | 14.4 mm | 2.1 mm | 2.47 mm | 30 mm | 9 mm | 1.98 mm |
| Value | | | | | | | | |
| Working | * | * | * | 1 mm- | 1 mm- | ** | ** | * |
| Range | | | | 5 mm** | 5 mm** | | | |

* Limited only by specific application & geometry constraints
**Limited by numerical aperture needed

Another aspect of the present invention is to provide a method of treating a surface of an ion trap during use. The method includes providing ion gun 100 and using the ion gun 100 to treat an inner surface region of the ion trap at a plurality of different times while the ion gun 100 remains incorporated into the ion trap. For example, the ion gun 100 can be used for surface cleaning for any system that is affected by electric field noise originating from surfaces, especially those requiring high optical access. Example applications include trapped ion quantum information processing systems and sensors, solid-state (e.g. diamond-based and SiC-based) quantum information processing systems and sensors, Rydberg-atom quantum information processing systems, cold atom gravitometers, and gyroscopes.

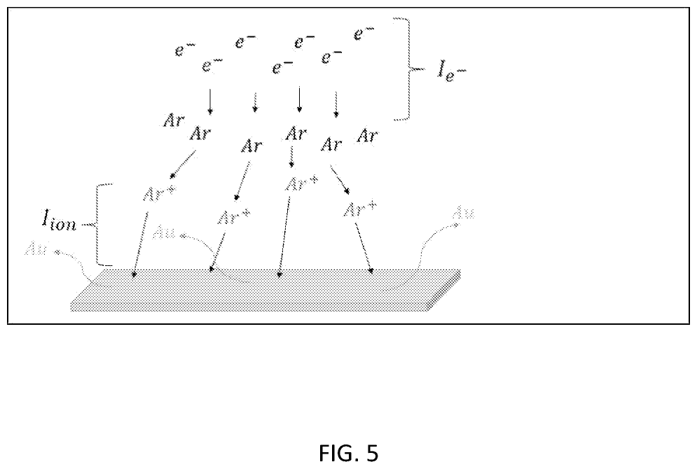

FIG. 5 is a schematic diagram illustrating a surface treatment technique of gold (Au) with Argon ions (Ar⁺), according to an embodiment of the present invention. Argon ions generated by the ion gun 100 (e.g., via electron impact on argon atoms) imping the gold surface. The surface having deposited thereon a gold layer can be the surface of the shield facing the ion trap. In an embodiment, a measured electron current is about 7.5 mAmp and the measured flux (current/area) is about 122 nAMP/mm². However, as it must be appreciated, the operating electron current and flux are not limited to these values and can be other values depending on the desired amount of ion and desired energy of the ions.

The embodiments illustrated and discussed in this specification are intended only to teach those skilled in the art how to make and use the invention. In describing embodiments of the disclosure, specific terminology is employed for the sake of clarity. However, the disclosure is not intended to be limited to the specific terminology so selected. The above-described embodiments of the disclosure may be modified or varied, without departing from the invention, as appreciated by those skilled in the art in light of the above teachings. It is therefore to be understood that, within the scope of the claims and their equivalents, the invention may be practiced otherwise than as specifically described. For example, it is to be understood that the present disclosure contemplates that, to the extent possible, one or more features of any embodiment can be combined with one or more features of any other embodiment.

1. An ion gun, comprising:
a confinement vessel defining a chamber therein;
a plasma source configured to provide ions in said chamber; and
at least one acceleration and focusing electrode disposed within said chamber and positioned to receive ions from said plasma source, and to accelerate and focus said ions received to be delivered to an underlying surface,
wherein said at least one acceleration and focusing electrode is structured to provide an aperture therethrough to provide optical access to a high numerical aperture optical device.

2. The ion gun of claim 1, wherein said at least one acceleration and focusing electrode comprises a basket electrode formed in a cylindrical shape, and arranged to accelerate and focus said ions in an axial direction of said basket electrode.

3. The ion gun of claim 2, wherein said at least one acceleration and focusing electrode further includes a shield arranged substantially perpendicular to and spaced apart from said basket electrode in an axial direction therefrom, said shield defining an aperture therethrough.

4. The ion gun of claim 2, wherein said at least one acceleration and focusing electrode is less than about 1.5 cm in height.

5. The ion gun of claim 1, wherein said underlying surface is a surface of an ion trap.

6. The ion gun of claim 3, further comprising:
a first voltage source connected to said basket electrode to provide a voltage V_{B}; and
a second voltage source connected to said shield to provide a voltage V_{S}.

7. The ion gun of claim 6, wherein, during operation, said first voltage source provides a voltage V_{B} of at least 100 V to about 2 kV, and said second voltage source provides a voltage V_{S} of at least 0 V to about V_{S}.

8. The ion gun of claim 6, wherein, during operation, said first voltage source provides a voltage V_{B} of at least 200 V to about 500 V, and said second voltage source provides a voltage V_{S} of at least 0 V to about V_{S}.

9. The ion gun of claim 6, wherein, during operation, said first voltage source provides a voltage V_{B} of about 300 V, and said second voltage source provides a voltage V_{S} of 300 V or less.

10. The ion gun of claim 1, wherein said plasma source comprises a filament connected to a power supply to provide energetic electrons to form a plasma from a supply gas.

11. The ion gun of claim 1, wherein said plasma source comprises a control valve to allow a supply gas to be delivered to said chamber.

12. The ion gun of claim 10, wherein, during operation, a voltage V_{F} is applied to the filament.

13. The ion gun of claim 10, wherein said power supply supplies a current of at least 2.6 A to about 10 A to said filament.

14. The ion gun of claim 10, wherein said power supply supplies a current of at least 4 A to about 17 A to said filament.

15. The ion gun of claim 10, wherein said power supply supplies a current of about 5.5 A to said filament.

16. An ion trap comprising an ion gun incorporated therein, said ion gun comprising:
a confinement vessel defining a chamber therein;
a plasma source configured to provide ions in said chamber; and
at least one acceleration and focusing electrode disposed within said chamber and positioned to receive ions from said plasma source, and to accelerate and focus said ions received to be delivered to an underlying surface,
wherein said at least one acceleration and focusing electrode is structured to provide an aperture therethrough to provide optical access to a high numerical aperture optical device.

17. An ion gun assembly, comprising:
an ion gun; and
a high numerical aperture optical device,
wherein the ion gun, comprises:
a confinement vessel defining a chamber therein;
a plasma source configured to provide ions in said chamber; and
at least one acceleration and focusing electrode disposed within said chamber and positioned to receive ions from said plasma source and accelerate and focus said ions received to be delivered to an underlying surface,
wherein said at least one acceleration and focusing electrode is structured to provide an aperture therethrough to provide optical access to the high numerical aperture optical device.

18. A method of treating a surface of an ion trap during use, comprising:
providing an ion gun incorporated into said ion trap said ion gun comprising:
a confinement vessel defining a chamber therein;
a plasma source configured to provide ions in said chamber; and
at least one acceleration and focusing electrode disposed within said chamber and positioned to receive ions from said plasma source, and to accelerate and focus said ions received to be delivered to an underlying surface,
wherein said at least one acceleration and focusing electrode is structured to provide an aperture therethrough to provide optical access to a high numerical aperture optical device; and
using said ion gun to treat an inner surface region of said ion trap at a plurality of different times while said ion gun remains incorporated into said ion trap.
